(19) United States
(12) Patent Application Publication
(10) Pub. No.: US 2012/0055698 A1
(43) Pub. Date: Mar. 8, 2012

(54) SINGLE LAYER PRINTED CIRCUIT BOARD AND METHOD FOR MANUFACTURNING THE SAME

(75) Inventors: Jo Youn WON, Daejeon (KR); Young IL CHO, Daejeon (KR); Jun Hyung SON, Chungcheongnam (KR)

(73) Assignee: SAMSUNG ELECTRO-MECHANICS CO., LTD., Gyunggi-do (KR)

(21) Appl. No.: 13/226,363

(22) Filed: Sep. 6, 2011

(30) Foreign Application Priority Data
Sep. 7, 2010 (KR) 10-2010-0087609

(51) Int. Cl. H05K 1/11; H05K 3/00

(52) U.S. Cl. 174/251; 29/829

(57) ABSTRACT

Disclosed herein are a single layer printed circuit board and a method for manufacturing the same. The single layer printed circuit board includes: an insulating layer having a plurality of holes, which are filled with a plating layer to form circuit patterns; a first protection layer stacked on one surface of the insulating layer to protect the circuit patterns formed in the insulating layer, the first protection layer having holes for exposing portions of the plating layer of the insulating layer; and a second protection layer formed on the opposite surface of the surface of the insulating layer, on which the first protection layer is formed, to protect the circuit patterns formed in the insulating layer. According to the present invention, a thin type printed circuit board can be provided.

### CROSS REFERENCE TO RELATED APPLICATION

This application claims the benefit of Korean Patent Application No. 10-2010-0087609, filed on Sep. 7, 2010, entitled “Single Layer Printed Circuit Board and Method for Manufacturing the Same”, which is hereby incorporated by reference in its entirety into this application.

### BACKGROUND OF THE INVENTION

1. Technical Field

The present invention relates to a single layer printed circuit board and a method for manufacturing the same.

2. Description of the Related Art

Generally, printed circuit boards are classified into a single layer printed circuit board, a double-sided printed circuit board, a multi-layer printed circuit board, and the like according to the processing method, and a phenol material printed circuit board or a glass or epoxy material printed circuit board according to the materials.

In the printed circuit boards classified as above, the single layer printed circuit board is manufactured through the process as shown in FIGS. 1 to 7.

In order to manufacture the single layer printed circuit board, first, as shown in FIG. 1, a copper foil 2 having a thickness of basically several tens of microns is attached onto an insulating layer 1 made of epoxy. Then, as shown in FIG. 2, a dry film 3 is coated on the copper foil 2.

Then, as shown in FIG. 3, a desired pattern is formed in the dry film 3 formed on the copper foil 2.

Next, as shown in FIG. 4, the pattern part formed in the dry film 3 is removed and a part of the copper foil 2 corresponding to the pattern part is further removed, through a developing process, thereby forming a pattern in the copper foil 2. Here, the pattern formed in the copper foil 2 has the same pattern as that formed in the dry film 3.

Then, as shown in FIG. 5, the dry film 3 is removed, thereby leaving the copper foil 2 having the same pattern as the pattern formed in the dry film 3, on the insulating layer 1.

Next, as shown in FIG. 6, a solder resist layer 4 is coated on the copper foil 2, and then, as shown in FIG. 7, a pattern is formed in the solder resist layer 4, thereby completing the manufacture of the single layer printed circuit board.

As such, the single layer printed circuit board according to the prior art use an epoxy material for a core layer, which causes the manufacture of a thin type printed circuit board to be difficult.

Furthermore, the single layer printed circuit board according to the prior art is manufactured by a plurality of processes including exposing, developing, etching, washing, and the like, which causes complicated processes. Furthermore, since patterns are formed by exposing, etching, developing, and washing of metal, most of the plated metal is etched, resulting in the waste of raw materials.

### SUMMARY OF THE INVENTION

The present invention has been made in an effort to provide a single layer printed circuit board capable of allowing a small thickness, simplifying the manufacturing process, and minimizing the waste of raw materials, by forming a plurality of holes on an insulating layer and filling a plating layer in the holes to form circuit patterns, and a method for manufacturing the same.

According to a preferred embodiment of the present invention, there is provided a single layer printed circuit board, including: an insulating layer having a plurality of holes, which are filled with a plating layer to form circuit patterns; a first protection layer stacked on one surface of the insulating layer to protect the circuit patterns formed in the insulating layer, the first protection layer having holes for exposing portions of the plating layer of the insulating layer; and a second protection layer formed on the opposite surface of the surface of the insulating layer, on which the first protection layer is formed, to protect the circuit patterns formed in the insulating layer.

The insulating layer may be made of prepreg.

The first protection layer and the second protection may be made of solder resist.

The second protection layer may have holes for exposing portions of the plating layer of the insulating layer.

The single layer printed circuit board may further include a surface treatment layer formed on a surface of the plating layer of the insulating layer, which is exposed through the holes of the first protection layer.

Further, according to a preferred embodiment of the present invention, there is provided a method for manufacturing a single layer printed circuit board, including: (A) preparing a carrier substrate where copper foils are formed above both surfaces of a first insulating layer with adhesive layers therebetween; (B) stacking a second insulating layer on one surface of the carrier substrate, forming holes in the second insulating layer, and forming a plating layer in the holes to form circuit patterns; (C) forming a first protection layer on one surface of the second insulating layer; (D) removing the carrier substrate where the copper foil is left on the other surface of the second insulating layer; and (E) removing the copper foil from the second insulating layer, forming a second protection layer on the surface from which the copper foil is removed, and forming holes in the first protection layer to expose the plating layer.

The method may further include: (F) forming a surface treatment layer on the plating layer exposed through the holes formed in the first protection layer, after step (E).

Step (B) may include: (B-1) stacking prepreg on one surface of the carrier substrate to form the second insulating layer; (B-2) forming the holes in the second insulating layer by using laser; and (B-3) forming the plating layer in the holes of the second insulating layer to form the circuit patterns.

Step (E) may include: (E-1) removing the copper foil from the second insulating layer through etching; (E-2) forming the second protection layer on the second insulating layer; and (E-3) forming the holes in the first protection layer to expose the plating layer.

Further, according to a preferred embodiment of the present invention, there is provided a method for manufacturing a single layer printed circuit board, including: (A) preparing a carrier substrate where copper foils are formed above both surfaces of a first insulating layer with adhesive layers therebetween; (B) stacking a second insulating layer and a third insulating layer on both surfaces of the carrier substrate, forming holes in the second and third insulating layers, and forming plating layers in the holes to form circuit patterns; (C) forming a first protection layer on one surface of the second insulating layer and a second protection layer on one surface of the third insulating layer; (D) removing the carrier substrate where the copper foils are left on the other surface of the second insulating layer and the other surface of the third insulating layer, respectively; (E) removing the copper foil from the second insulating layer, forming a third protection layer on the surface of the second insulating layer from which the copper foil is removed, and forming holes in the first protection layer to expose the plating layer; and (F) removing the copper foil from the third insulating layer, forming a fourth protection layer on the surface of the third insulating layer from which the copper foil is removed, and forming holes in the second protection layer to expose the plating layer.

The method may further include: (G) forming surface treatment layers on the plating layers exposed through the holes formed in the first and second protection layers, after step (F).

Step (B) may include: (B-1) stacking prepreg on both surfaces of the carrier substrate to form the second and third insulating layers; (B-2) forming the holes in the second and third insulating layers by using laser; and (B-3) forming the plating layers in the holes of the second and third insulating layers to form the circuit patterns.

Step (E) may include: (E-1) removing the copper foil from the second insulating layer through etching; (E-2) forming the third protection layer on the second insulating layer; and (E-3) forming the holes in the first protection layer to expose the plating layer.

Step (F) may include: (E-1) removing the copper foil from the third insulating layer through etching; (E-2) forming the fourth protection layer on the third insulating layer; and (E-3) forming the holes in the second protection layer to expose the plating layer.

### BRIEF DESCRIPTION OF THE DRAWINGS

FIGS. 1 to 7 are process views showing a method for manufacturing a single layer printed circuit board according to the prior art;

FIG. 8 is a cross-sectional view of a single layer printed circuit board according to a first preferred embodiment of the present invention;

FIGS. 9 to 15 are process views showing a method for manufacturing a single layer printed circuit board according to a first preferred embodiment of the present invention; and

FIGS. 16 to 22 are process views showing a method for manufacturing a single layer printed circuit board according to a second preferred embodiment of the present invention.

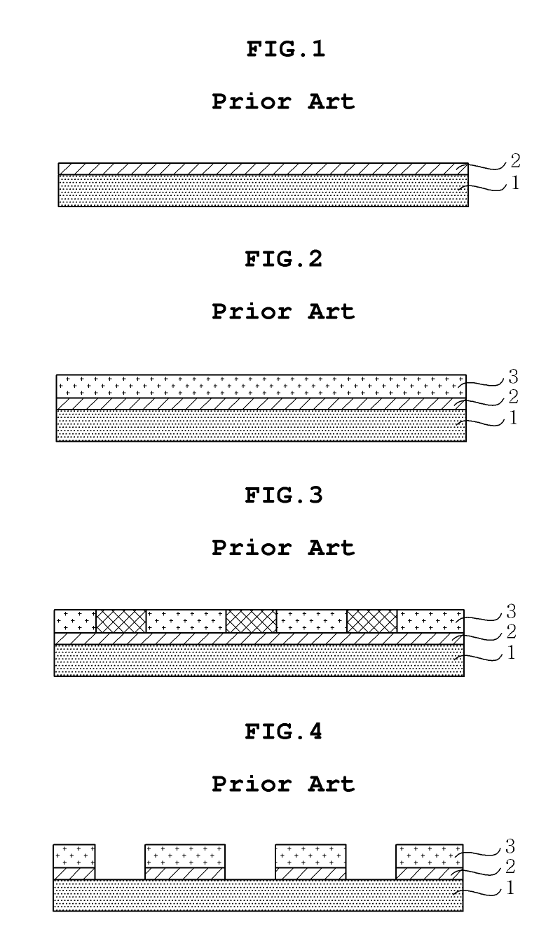

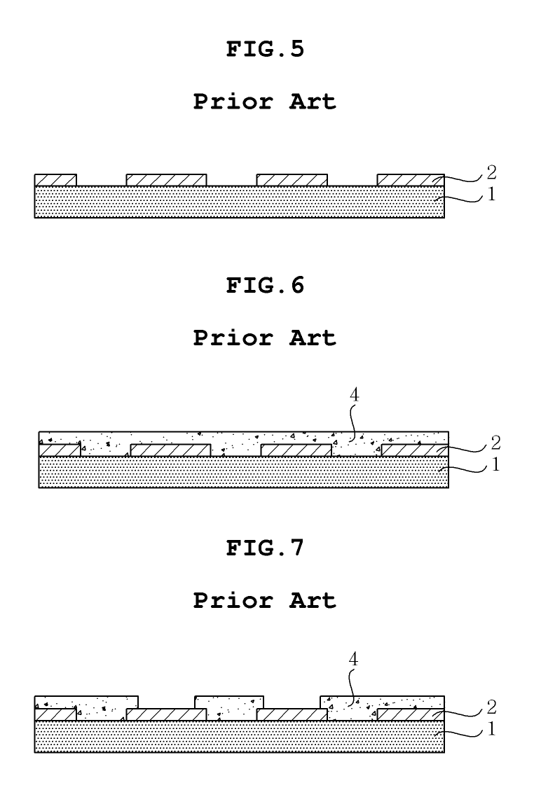

### DESCRIPTION OF THE PREFERRED EMBODIMENTS

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

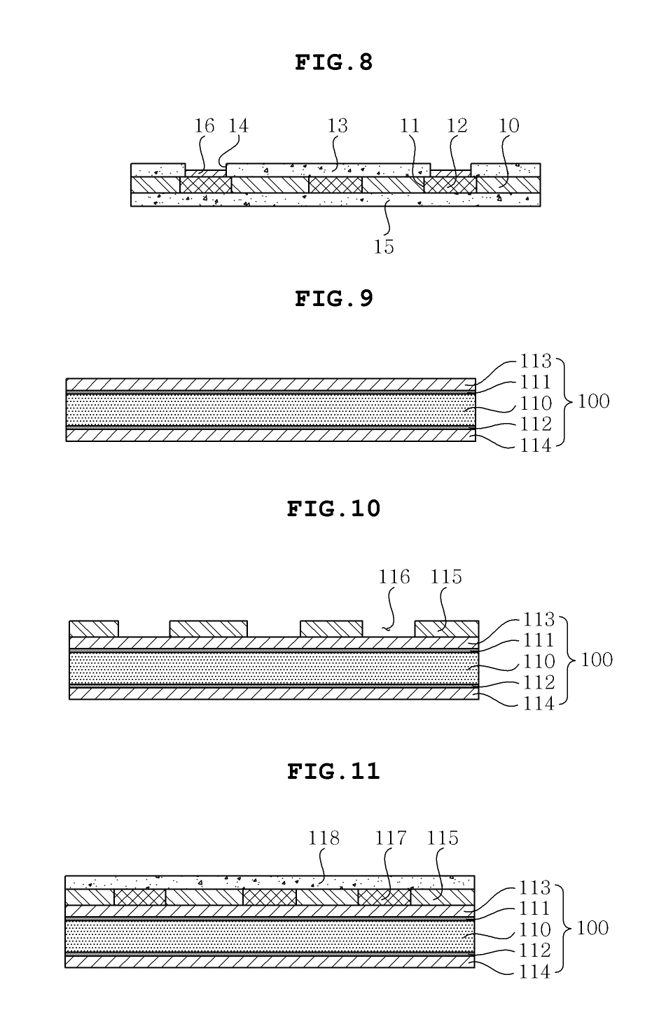

FIG. 8 is a cross-sectional view of a single layer printed circuit board according to a first preferred embodiment of the present invention.

Referring to the drawings, a single layer printed circuit board according to a first preferred embodiment of the present invention includes: an insulating layer 10 having a plurality of holes 11, which are filled with a plating layer 12 to form circuit patterns, a first protection layer 13 formed on one surface of the insulating layer 10 to protect the circuit patterns formed in the insulating layer 10 and having a plurality of holes 14 to expose portions of the plating layer 12 of the insulating layer 10, and a second protection layer 15 formed on the opposite surface of the surface of the insulating layer 10, on which the first protection layer 13 is formed, to protect the circuit patterns formed in the insulating layer 10.

Here, the insulating layer 10 is preferable made of prepreg, and the first protection layer 13 and the second protection layer 15 are preferably made of solder resist.

The plating layer 12 formed in the insulating layer 10 is preferably a copper plating layer, and the portions of the plating layer which are exposed through the holes 14 formed in the first protection layer 13 are treated with a surface treatment layer 16. This surface treatment layer 16 is preferably made of a Ni plating layer and an Au plating layer.

Meanwhile, holes are not formed in the second protection layer 15, but holes may be formed to expose desired portions of the plating layer 12 formed in the insulating layer 10 as necessary.

FIGS. 9 to 15 are process views showing a method for manufacturing a single layer printed circuit board according to a first preferred embodiment of the present invention.

Referring to FIG. 9, in order to manufacture a single layer printed circuit board according to a first preferred embodiment of the present invention, a carrier substrate 100, which is made of a copper clad laminate (CCL) where copper foils 113 and 114 are stacked above both surfaces of an insulating layer 110 with adhesive layers 111 and 112 therebetween, is prepared. Here, the conductive adhesive layer that can be easily separated from both sides by application of heat or UV and then can be used when a plating layer is formed is preferably used as the adhesive layers 111 and 112.

Then, as shown in FIG. 10, an insulating layer 115 made of, for example, prepreg, is stacked on one surface of the carrier substrate 100, and holes 116 are formed therein.

Here, the holes 116 formed in the insulating layer 115 may be formed by using laser, and the usable laser may include a CO₂ laser.

Next, as shown in FIG. 11, a plating process is performed to fill the insides of the holes 116 with a plating layer 117, thereby forming circuit patterns along the holes 116 formed in the insulating layer 115. Here, a solder resist ink is coated and hardened on one surface of the insulating layer 115 to form a solder resist layer 118 (a first protection layer), in order to protect the circuit patterns formed in the insulating layer 115 and prevent a solder bridge phenomenon between the circuit patterns in a soldering process.

Here, with respect to a method of filling the insides of the holes 16 formed in the insulating layer 15, electrolytic copper plating or electroless copper plating may be performed by using the adhesive layer 111 made of a conductive adhesive as a seed layer, thereby forming the plating layer 117 made of a copper plating layer.

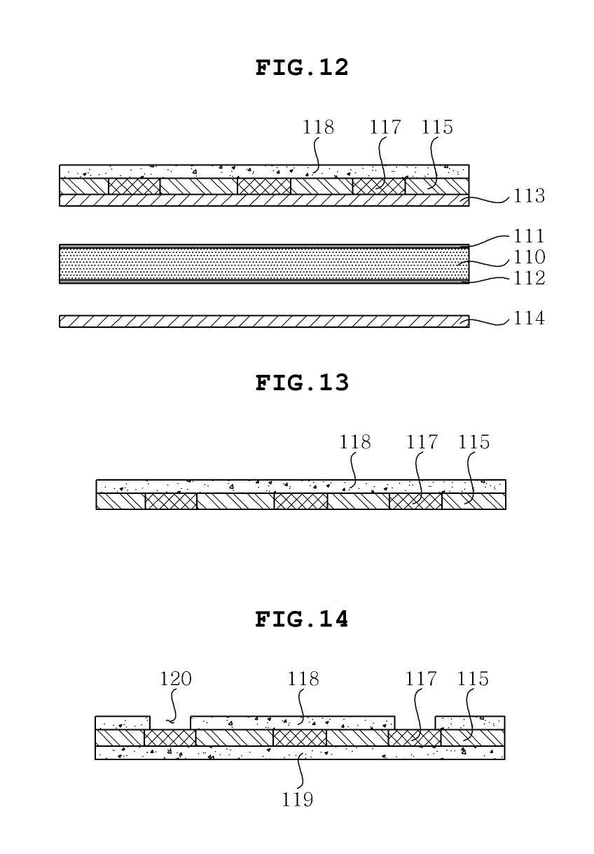

Then, as shown in FIG. 12, the adhesive layer 111 is peeled off by application of heat or UV to separate a laminate structure body formed on one surface of the carrier substrate 100 from the carrier substrate 100. Here, since the carrier substrate 100 and the laminate structure body are separated from each other by peeling off the adhesive layer 111, the copper foil 113 is attached to the laminate structure body.

Therefore, as shown in FIG. 13, the copper foil 113 is removed through alkaline etching, thereby obtaining a laminate structure body from which the copper foil 13 is removed.

Next, as shown in FIG. 14, a photo imagable solder resist mask ink (PSR ink) is coated on the opposite surface of the laminate structure body to form a solder resist layer 119 (a second protection layer), in order to protect the circuit patterns formed in the insulating layer 115 and prevent a solder bridge phenomenon between the circuit patterns in a soldering process.

Simultaneously with this or subsequently to this, in order to expose a portion of the plating layer 117 formed in the insulating layer 115, a hardening treatment is performed on the previously formed solder resist layer 118 by using a diazo film having circuit patterns, thereby removing a portion of the solder resist coated on the region where the portion of plating layer 117 is to be exposed.

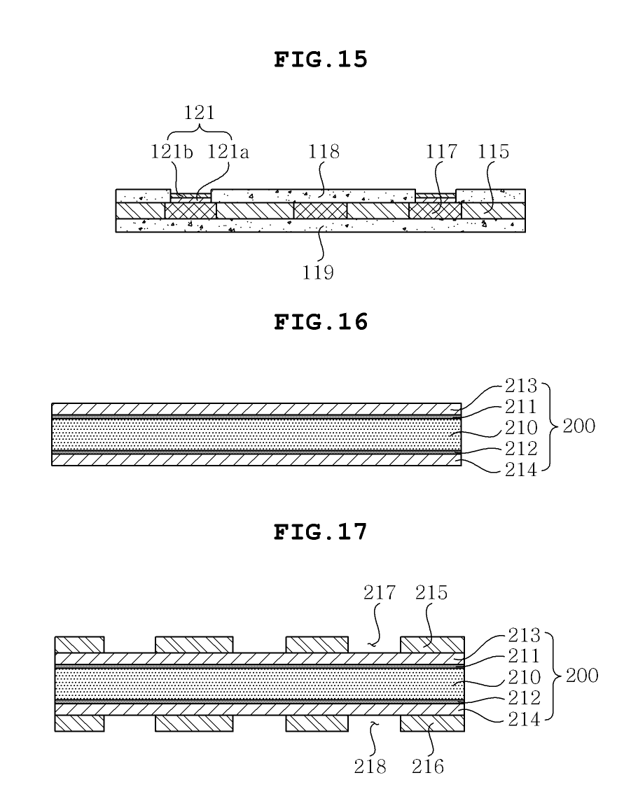

As described above, after removing the portion of the solder resist layer 118, electrolytic or electroless gold plating is performed on the exposed portion of the plating layer 117, thereby forming a surface treatment layer 121 made of a Ni/Au plating layer to prevent the exposed portion of the plating layer 117 from being oxidized, as shown in FIG. 15.

More specifically, nickel plating is performed on the exposed portion of the plating layer 117 to form a nickel plating layer 121a having a predetermined height. Then, gold plating is performed on the nickel plating layer 121a formed by nickel plating to form a gold plating layer 121b having a predetermined height in order to secure affinity with solder, thereby completing the surface treatment layer 121.

FIGS. 16 to 22 are process views showing a method for manufacturing a single layer printed circuit board according to a second preferred embodiment of the present invention.

Referring to FIG. 16, in order to manufacture a single layer printed circuit board according to a second preferred embodiment of the present invention, a carrier substrate 200, which is made of a copper clad laminate (CCL) where copper foils 213 and 214 are stacked above both surfaces of an insulating layer 210 with adhesive layers 211 and 112 therebetween, is prepared. For example of the present invention, conductive adhesive that can be easily separated by application of heat or UV and then can be used as a seed layer of electrolytic plating is preferably used as the adhesive layers 211 and 212.

Then, as shown in FIG. 17, insulating layers 215 and 216 are formed on both surfaces of the carrier substrate 200 by stacking, for example, prepreg, and then holes 217 and 218 are formed in the insulating layers 215 and 216.

Here, the holes may be formed in the insulating layers by using laser, and the usable laser may include a CO₂ laser.

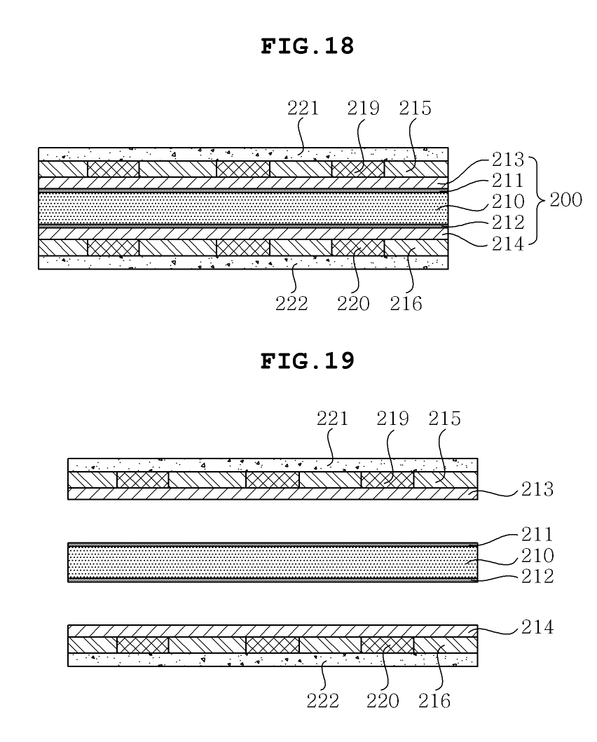

Next, as shown in FIG. 18, a plating process is performed to fill the insides of the holes 217 and 218 with plating layers 219 and 220, thereby forming circuit patterns along the holes 217 and 218 formed in the insulating layers 215 and 216. Here, a solder resist ink is coated on one surface of each of the insulating layers 215 and 216 to form solder resist layers 221 and 222 (first and second protection layers), in order to protect the circuit patterns formed in the insulating layers 215 and 216 and prevent a solder bridge phenomenon between the circuit patterns in a soldering process.

Here, with respect to a method of filling the insides of the holes 217 and 218 formed in the insulating layers 215 and 216, electrolytic copper plating or electroless copper plating may be performed by using the adhesive layers 211 and 212 made of conductive adhesive as seed layers, thereby forming the copper plating layers.

Then, as shown in FIG. 19, the adhesive layers 211 and 212 are peeled off by application of heat or UV to separate laminate structure bodies formed on both surfaces of the carrier substrate 200 from the carrier substrate 200. Here, since the carrier substrate 200 and the laminate structure bodies are separated from each other by peeling off the adhesive layers 211 and 212, the copper foils 213 and 214 are attached to the laminate structure bodies, respectively.

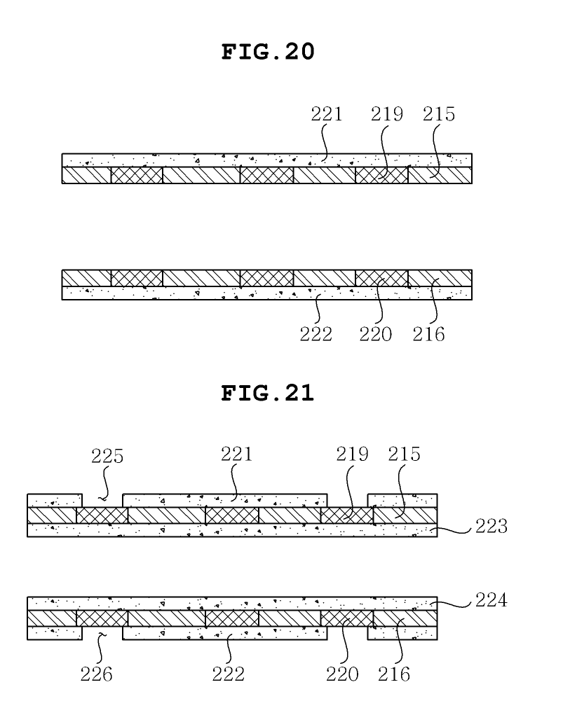

Therefore, as shown in FIG. 20, the copper foils 213 and 214 are respectively removed through alkaline etching, thereby obtaining two laminate structure bodies from which the copper foils 213 and 214 are removed.

Next, as shown in FIG. 21, a photo imagable solder resist mask ink (PSR ink) is coated on the opposite surfaces of the laminate structure bodies to form solder resist layers 223 and 224 (third protection layer and fourth protection layer), in order to protect the circuit patterns formed in the insulating layers 215 and 216 and prevent a solder bridge phenomenon between the circuit patterns in a soldering process.

Simultaneously with this or subsequently to this, a hardening treatment is performed on the previously formed solder resist layers 223 and 224 by using diazo films having circuit patterns for exposing portions of the plating layers 219 and 220 formed in the insulating layers 215 and 216, thereby removing portions of the solder resist layers 223 and 224 coated on the region where the portions of plating layers 219 and 22 are to be exposed, thereby exposing the portions of the plating layers 219 and 220 formed in the insulating layers 215 and 216.

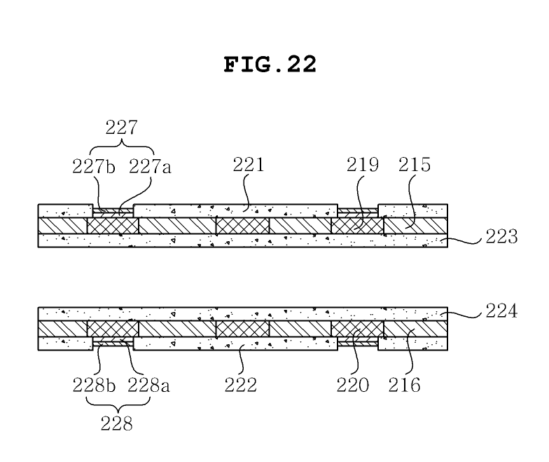

As described above, after exposing the portions of the plating layers 219 and 220, electrolytic or electroless gold plating is performed on the exposed portions of the plating layers 219 and 220, thereby forming surface treatment layers 227 and 228 made of a Ni/Au plating layer to prevent the exposed portion of the plating layers 219 and 220 from being oxidized, as shown in FIG. 22.

More specifically, nickel plating is performed on the exposed portions of the plating layers 219 and 220 to form nickel plating layers 227a and 228a having a predetermined height. Then, gold plating is performed on the nickel plating layers 227a and 228a formed by nickel plating to form gold plating layers 227b and 228b having a predetermined height in order to secure affinity with solder.

According to the present invention, a printed circuit board having a small thickness can be provided, by using the insulating layer having a plurality of holes, which are then filled with the plating layer to form the circuit patterns.

Further, according to the present invention, the manufacturing process can be simplified, by using the carrier substrate when the single layer printed circuit board is manufactured.

Moreover, according to the present invention, waste of raw materials can be minimized by filling the holes with the plating layer to form the circuit patterns.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A single layer printed circuit board, comprising:
an insulating layer having a plurality of holes, which are filled with a plating layer to form circuit patterns;
a first protection layer stacked on one surface of the insulating layer to protect the circuit patterns formed in the insulating layer, the first protection layer having holes for exposing portions of the plating layer of the insulating layer; and
a second protection layer formed on the opposite surface of the surface of the insulating layer, on which the first protection layer is formed, to protect the circuit patterns formed in the insulating layer.

2. The single layer printed circuit board as set forth in claim 1, wherein the insulating layer is made of prepreg.

3. The single layer printed circuit board as set forth in claim 1, wherein the first protection layer and the second protection are made of solder resist.

4. The single layer printed circuit board as set forth in claim 1, wherein the second protection layer has holes for exposing portions of the plating layer of the insulating layer.

5. The single layer printed circuit board as set forth in claim 1, further comprising a surface treatment layer formed on a surface of the plating layer of the insulating layer, which is exposed through the holes of the first protection layer.

6. A method for manufacturing a single layer printed circuit board, comprising:
(A) preparing a carrier substrate where copper foils are formed above both surfaces of a first insulating layer with adhesive layers therebetween;
(B) stacking a second insulating layer on one surface of the carrier substrate, forming holes in the second insulating layer, and forming a plating layer in the holes to form circuit patterns;
(C) forming a first protection layer on one surface of the second insulating layer;
(D) removing the carrier substrate where the copper foil is left on the other surface of the second insulating layer; and
(E) removing the copper foil from the second insulating layer, forming a second protection layer on the surface from which the copper foil is removed, and forming holes in the first protection layer to expose the plating layer.

7. The method as set forth in claim 6, further comprising:
(F) forming a surface treatment layer on the plating layer exposed through the holes formed in the first protection layer, after step (E).

8. The method as set forth in claim 6, wherein step (B) includes:
(B-1) stacking prepreg on one surface of the carrier substrate to form the second insulating layer;
(B-2) forming the holes in the second insulating layer by using laser; and
(B-3) forming the plating layer in the holes of the second insulating layer to form the circuit patterns.

9. The method as set forth in claim 6, wherein step (E) includes:
(E-1) removing the copper foil from the second insulating layer through etching;
(E-2) forming the second protection layer on the second insulating layer; and
(E-3) forming the holes in the first protection layer to expose the plating layer.

10. A method for manufacturing a single layer printed circuit board, comprising:
(A) preparing a carrier substrate where copper foils are formed above both surfaces of a first insulating layer with adhesive layers therebetween;
(B) stacking a second insulating layer and a third insulating layer on both surfaces of the carrier substrate, forming holes in the second and third insulating layers, and forming plating layers in the holes to form circuit patterns;
(C) forming a first protection layer on one surface of the second insulating layer and a second protection layer on one surface of the third insulating layer;
(D) removing the carrier substrate where the copper foils are left on the other surface of the second insulating layer and the other surface of the third insulating layer, respectively;
(E) removing the copper foil from the second insulating layer, forming a third protection layer on the surface of the second insulating layer from which the copper foil is removed, and forming holes in the first protection layer to expose the plating layer; and
(F) removing the copper foil from the third insulating layer, forming a fourth protection layer on the surface of the third insulating layer from which the copper foil is removed, and forming holes in the second protection layer to expose the plating layer.

11. The method as set forth in claim 10, further comprising (G) forming surface treatment layers on the plating layers exposed through the holes formed in the first and second protection layers, after step (F).

12. The method as set forth in claim 10, wherein step (B) includes:
(B-1) stacking prepreg on both surfaces of the carrier substrate to form the second and third insulating layers;
(B-2) forming the holes in the second and third insulating layers by using laser; and
(B-3) forming the plating layers in the holes of the second and third insulating layers to form the circuit patterns.

13. The method as set forth in claim 10, wherein step (E) includes:
(E-1) removing the copper foil from the second insulating layer through etching;
(E-2) forming the third protection layer on the second insulating layer; and
(E-3) forming the holes in the first protection layer to expose the plating layer.

14. The method as set forth in claim 10, wherein step (F) includes:
(E-1) removing the copper foil from the third insulating layer through etching;
(E-2) forming the fourth protection layer on the third insulating layer; and
(E-3) forming the holes in the second protection layer to expose the plating layer.
